(19) United States
(12) Patent Application Publication
(10) Pub. No.: US 2013/0037808 A1
(43) Pub. Date: Feb. 14, 2013

(54) THIN-FILM TRANSISTOR DEVICE AND METHOD FOR MANUFACTURING THIN-FILM TRANSISTOR DEVICE

(71) Applicant: PANASONIC CORPORATION, Osaka (JP)

(72) Inventors: Yuji KISHIDA, Hyogo (JP); Hiroshi HAYASHI, Osaka (JP); Takahiro KAWASHIMA, Osaka (JP); Kenichirou NISHIDA, Osaka (JP)

(73) Assignee: PANASONIC CORPORATION, Osaka (JP)

(21) Appl. No.: 13/632,607

(22) Filed: Oct. 1, 2012

Related U.S. Application Data
(63) Continuation of application No. PCT/JP2011/004541, filed on Aug. 10, 2011.

(51) Int. Cl. H01L 29/786; H01L 21/336

(52) U.S. Cl. 257/57; 438/158; 257/E29.273; 257/E21.412

(57) ABSTRACT

A thin-film transistor device which is a bottom-gate thin-film transistor device, includes: a gate electrode formed above a substrate; a gate insulating film formed above the gate electrode; a crystalline silicon thin film formed above the gate insulating film and having a channel region; an amorphous silicon thin film formed above the crystalline silicon thin film including the channel region; and a source electrode and a drain electrode formed above the amorphous silicon thin film, in which an optical bandgap of the amorphous silicon thin film and an off-state current of the thin-film transistor device have a positive correlation.

### CROSS REFERENCE TO RELATED APPLICATION

This is a continuation application of PCT Patent Application No. PCT/JP2011/004541 filed on Aug. 10, 2011, designating the United States of America. The entire disclosure of the above-identified application, including the specification, drawings and claims is incorporated herein by reference in its entirety.

### TECHNICAL FIELD

One or more exemplary embodiments disclosed herein relate generally to thin-film transistor devices and methods for manufacturing the thin-film transistor devices, and particularly to a bottom-gate thin-film transistor device and a method for manufacturing the bottom-gate thin-film transistor device.

### BACKGROUND ART

In an active-matrix display device such as liquid crystal display device, a thin-film transistor device referred to as a thin-film transistor (TFT) has been used. In the display device, the TFT is used as a switching device for selecting a pixel or a driving transistor for driving the pixel.

In recent years, organic EL displays using electroluminescence (EL) of an organic material have been attracting attention as a type of next-generation flat panel display replacing liquid crystal displays. Unlike the voltage-driven liquid crystal display, the organic EL display is a current-driven display device. Accordingly, there is an urgent need for development of a thin-film transistor device having excellent on/off-characteristics as a driving circuit for the active-matrix display device

Conventionally, there is a thin-film transistor device in which a single-layer amorphous semiconductor layer is used as the thin-film transistor device in a driving circuit for a liquid crystal display. A problem in this type of thin-film transistor device is that an on-state current (drain current when the gate is turned on) is low due to low charge mobility, although the off-state current (leakage current when the gate is turned off) is low due to a large bandgap of the channel layer.

In response to this problem, a thin-film transistor device has been proposed in which the channel layer has a two-layer structure including a crystalline silicon thin film and an amorphous silicon thin film. As described above, by having the two-layer structure including the crystalline silicon thin film and the amorphous silicon thin film as the channel layer, it is assumed that advantages of the both layers ideally allow an increase in the off-state current compared to a thin-film transistor device having a channel layer made of a single-layer amorphous silicon thin film and a reduction in the on-state current, compared to a thin-film transistor device having a channel layer made of a single-layer crystalline silicon thin film.

For example, the patent literature 1 discloses a thin-film transistor device having a channel layer with a two-layer structure of a microcrystalline silicon film and an amorphous silicon film. According to the thin-film transistor device disclosed in the patent literature 1, it is possible to suppress variation in the on-state current and suppress the change in the threshold voltage Vth.

### CITATION LIST

### Patent Literature

[Patent Literature 1] Japanese Unexamined Patent Application Publication No. 2007-5508

### SUMMARY

### Technical Problem

However, simply having the channel layer with the two-layer structure of the crystalline silicon thin film and the amorphous silicon thin film does not necessarily increase the on-state current and reduce the off-state current. For example, if the thickness of the amorphous silicon thin film is increased to reduce the off-state current, the on-state resistance increases, reducing the on-state current.

As described above, in the thin-film transistor device in which the channel layer has the two-layer structure of the crystalline silicon thin film and the amorphous silicon thin film, it is difficult to secure the on-state current while suppressing the off-state current.

One non-limiting and exemplary embodiment provides a thin-film transistor device and a method for manufacturing the thin-film transistor device capable of securing the on-state current and suppressing the off-state current, even if the channel layer in the thin-film transistor device is made of a stacked structure of the amorphous silicon thin film and the amorphous silicon thin film.

### Solution to Problem

In one general aspect, the thin-film transistor device disclosed here feature a thin-film transistor device which is a bottom-gate thin-film transistor device, including: a gate electrode above a substrate; a gate insulating film above the gate electrode; a crystalline silicon thin film comprising a channel region, the crystalline silicon thin film being above the gate insulating film and having a channel region; an amorphous silicon thin film above the crystalline silicon thin film including the channel region; and a source electrode and a drain electrode above the amorphous silicon thin film, in which an optical bandgap of the amorphous silicon thin film and an off-state current of the thin-film transistor device have a positive correlation.

Additional benefits and advantages of the disclosed embodiments will be apparent from the Specification and Drawings. The benefits and/or advantages may be individually obtained by the various embodiments and features of the Specification and Drawings, which need not all be provided in order to obtain one or more of such benefits and/or advantages.

### Advantageous Effects

One or more exemplary embodiments or features disclosed herein provide the thin-film transistor device capable of securing the on-state current and suppressing the off-state current in the thin-film transistor device having the channel layer with the stacked structure of the crystalline silicon thin film and the amorphous silicon thin film.

### BRIEF DESCRIPTION OF DRAWINGS

These and other advantages and features will become apparent from the following description thereof taken in conjunction with the accompanying Drawings, by way of non-limiting examples of embodiments of the present disclosure.

FIG. 1 is a cross-sectional view schematically illustrating a configuration of a thin-film transistor device according to an exemplary embodiment.

FIG. 2 illustrates a relationship between an optical bandgap of the channel layer and the off-state current in a general thin-film transistor device having a single-layer channel layer.

FIG. 3A illustrates a relationship between (i) the optical bandgap of the amorphous silicon thin film and (ii) the off-leakage current (off-state current) or the on-state resistance in the thin-film transistor device according to the embodiment.

FIG. 3B illustrates a relationship between (i) the optical bandgap and (ii) a conduction band or a valence band of the amorphous silicon thin film in the thin-film transistor device.

FIG. 4 illustrates a relationship between a thickness of the amorphous silicon thin film and an off-leakage current in the thin-film transistor device according to the embodiment.

FIG. 5 illustrates a relationship between a thickness of the amorphous silicon thin film and an on-state resistance in the thin-film transistor device according to the embodiment.

FIG. 6A illustrates a relationship between the thickness of the amorphous silicon thin film, the optical bandgap and the off-leakage current of the amorphous silicon thin film in the thin-film transistor device according to the embodiment.

FIG. 6B illustrates a relationship between the thickness of the amorphous silicon thin film, the optical bandgap and the on-state resistance of the amorphous silicon thin film in the thin-film transistor device according to the embodiment.

FIG. 6C illustrates an optimal range (process window) of the thickness and the optical bandgap of the amorphous silicon thin film in the thin-film transistor device according to the embodiment, for suitably balancing the off-leakage current and the on-state resistance.

FIG. 7A is a cross-sectional view schematically illustrating a substrate preparation process in a method for manufacturing the thin-film transistor device according to the embodiment.

FIG. 7B is a cross-sectional view schematically illustrating a gate electrode forming process in the method for manufacturing the thin-film transistor device according to the embodiment.

FIG. 7C is a cross-sectional view schematically illustrating a gate insulating film forming process in the method for manufacturing the thin-film transistor device according to the embodiment.

FIG. 7D is a cross-sectional view schematically illustrating a crystalline silicon thin film forming process in the method for manufacturing the thin-film transistor device according to the embodiment.

FIG. 7E is a cross-sectional view schematically illustrating an amorphous silicon thin film forming process in the method for manufacturing the thin-film transistor device according to the embodiment.

FIG. 7F is a cross-sectional view schematically illustrating an insulating layer forming process in the method for manufacturing the thin-film transistor device according to the embodiment.

FIG. 7G is a cross-sectional view schematically illustrating a contact layer forming process and a source/drain electrode forming process in the method for manufacturing the thin-film transistor device according to the embodiment.

### DESCRIPTION OF EMBODIMENT

The thin-film transistor device according to an aspect of the present disclosure is a thin-film transistor device which is a bottom-gate thin-film transistor device, including: a gate electrode above a substrate; a gate insulating film above the gate electrode; a crystalline silicon thin film comprising a channel region, the crystalline silicon thin film being above the gate insulating film and having a channel region; an amorphous silicon thin film above the crystalline silicon thin film including the channel region; and a source electrode and a drain electrode above the amorphous silicon thin film, in which an optical bandgap of the amorphous silicon thin film and an off-state current of the thin-film transistor device have a positive correlation.

According to this aspect, the optical bandgap of the amorphous silicon thin-film and the off-leakage current in the thin-film transistor device has a positive correlation. Accordingly, by controlling the optical bandgap Eg of the amorphous silicon thin film, it is possible to suppress a sharp increase in the off-leakage current on a front-channel side, securing the on-state current while suppressing the off-state current.

Furthermore, in an aspect of the thin-film transistor device according to the present disclosure, for example, an optical bandgap of the amorphous silicon thin film is at least 1.65 eV and at most 1.75 eV, and a potential of the amorphous silicon thin film is higher than a potential of the crystalline silicon thin film when an off-state voltage of the thin-film transistor device is applied to the gate electrode.

Furthermore, in an aspect of the thin-film transistor device according to the present disclosure, for example, expressions Eg≦0.01×t+1.55 and Eg≧0.0125×t+1.41 are satisfied, where Eg (eV) represents an optical bandgap of the amorphous silicon thin film and t (nm) represents a thickness of the amorphous silicon thin film.

Furthermore, in an aspect of the thin-film transistor device according to the present disclosure, for example, the amorphous silicon thin film has a thickness of at least 10 nm and at most 40 nm.

Furthermore, in an aspect of the thin-film transistor device according to the present disclosure, an insulating layer above the gate electrode and above the amorphous silicon thin film is further included, for example.

Furthermore, in an aspect of the thin-film transistor device according to the present disclosure, a pair of contact layers formed between the amorphous silicon thin film and the source electrode and between the amorphous silicon thin film and the drain electrode is further included, in which the pair of contact layers is not formed on a side surface of the amorphous silicon thin film or on a side surface of the crystalline silicon thin film, for example.

An aspect of a method for manufacturing a thin-film transistor device according the present disclosure is a method for manufacturing a thin-film transistor device which is a bottom-gate thin-film transistor device, the method including: preparing a substrate; forming a gate electrode above the substrate; forming a gate insulating film above the gate electrode; forming, above the gate insulating film, a crystalline silicon thin film having a channel region; forming an amorphous silicon thin film above the crystalline silicon thin film including the channel region; and forming a source electrode and a drain electrode above the amorphous silicon thin film, in which the amorphous silicon thin film is formed such that an optical bandgap of the amorphous silicon thin film and an off-state current of the thin-film transistor device have a positive correlation.

According to this aspect, the optical bandgap of the amorphous silicon thin-film and the off-leakage current in the thin-film transistor device has a positive correlation. Accordingly, by controlling the optical bandgap Eg of the amorphous silicon thin film, it is possible to suppress the sharp increase in the off-state current on the front-channel side, securing the on-state current while suppressing the off-state current.

Furthermore, in an aspect of the thin-film transistor device according to the present disclosure, the amorphous silicon thin film is formed by a radio-frequency (RF) plasma chemical vapor deposition (CVD) apparatus having parallel-plate electrodes under a film-forming condition in which: a temperature of the substrate set in the apparatus is at least 300° C. and at most 400° C.; SiH₄ gas is introduced to the apparatus at a flow rate at least 50 sccm and at most 60 sccm, and H₂ gas is introduced to the apparatus at a flow rate at least 6 sccm and at most 17 sccm; a pressure in the apparatus is at least 450 Pa and at most 850 Pa; a distance between the parallel-plate electrodes is at least 350 mm and at most 680 mm; and a density of an RF power applied to the parallel-plate electrodes is at least 0.0685 W/cm² and at most 0.274 W/cm², for example.

Furthermore, in an aspect of the thin-film transistor device according to the present disclosure, the amorphous silicon thin film is formed such that an optical bandgap of the amorphous silicon thin film is at least 1.65 eV and at most 1.75 eV, and when a voltage is not applied to the gate electrode, a potential of the amorphous silicon thin film is higher than a potential of the crystalline silicon thin film, for example.

Furthermore, in an aspect of the thin-film transistor device according to the present disclosure, the amorphous silicon thin film is formed such that expressions Eg≦0.01×t+1.55 and Eg≧0.0125×t+1.41 are satisfied, where Eg (eV) represents an optical bandgap of the amorphous silicon thin film and t (nm) represents a thickness of the amorphous silicon thin film, for example.

Furthermore, an aspect of the thin-film transistor device according to the present disclosure includes, for example, forming an insulating layer above the gate electrode and above the amorphous silicon thin film, after the amorphous silicon thin film is formed and before the source electrode and the drain electrode are formed.

A thin-film transistor device which is a bottom-gate thin-film transistor device, includes: a gate electrode above a substrate; a gate insulating film above the gate electrode; a crystalline silicon thin film including a channel region, the crystalline silicon thin film being above the gate insulating film; an amorphous silicon thin film above the crystalline silicon thin film including the channel region; and a source electrode and a drain electrode above the amorphous silicon thin film, in which an optical bandgap of the amorphous silicon thin film is at least 1.65 eV and at most 1.75 eV, and a potential of the amorphous silicon thin film is higher than a potential of the crystalline silicon thin film when an off-state voltage of the thin-film transistor device is applied to the gate electrode, and wherein expressions Eg≦0.01×t+1.55 and Eg≧0.0125×t+1.41 are satisfied, where Eg (eV) represents the optical bandgap of the amorphous silicon thin film and t (nm) represents a thickness of the amorphous silicon thin film.

### Embodiment

The following shall describe a thin-film transistor device and a method for manufacturing the thin-film transistor device based on an embodiment. However, the present disclosure is defined based on the recitations in Claims. Accordingly, among components in the embodiment, the components not recited in Claims are not necessary for solving the problem, but composes a more preferable embodiment. Note that, the diagrams are schematic diagrams, and the illustration is not always strictly accurate.

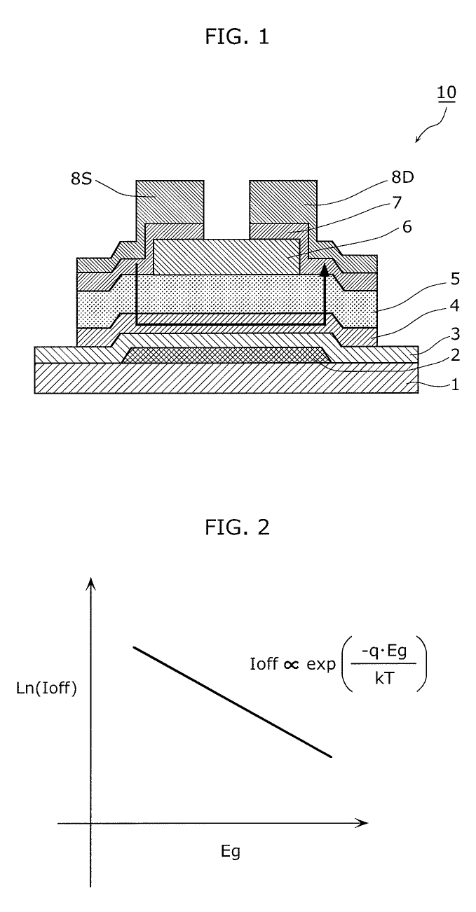

First, the configuration of the thin-film transistor device 10 according to the embodiment shall be described with reference to FIG. 1. FIG. 1 is a cross-sectional view schematically illustrating the thin-film transistor device according to the embodiment.

As illustrated in FIG. 1, the thin-film transistor device 10 according to the embodiment is channel-protective, and is a bottom-gate thin-film transistor including: a substrate 1; a gate electrode 2 formed above the substrate 1; a gate insulating film 3 formed above the gate electrode 2; a crystalline silicon thin film 4 formed above the gate insulating film 3; an amorphous silicon thin film 5 formed above the crystalline silicon thin film 4; an insulating layer 6 formed above the amorphous silicon thin film 5; and a source electrode 8S and a drain electrode 8D formed above the amorphous silicon thin film 5 with the insulating layer 6 provided in between. Furthermore, above the crystalline silicon thin film 4, the thin-film transistor device 10 according to the embodiment includes a pair of contact layers 7 formed between the amorphous silicon thin film 5 and the source electrode 8S or the drain electrode 8D. The following shall describe components of the thin-film transistor device 10 according to the embodiment.

The substrate 1 is a glass substrate made of, for example, a glass material such as silica glass, alkali-free glass, or highly heat-resistant glass. An undercoat layer made of a silicon nitride (SiNₓ) film, a silicon oxide (SiO_{y}) film, a silicon oxynitride (SiO_{y}Nₓ) film, or others may be formed on the substrate 1 in order to prevent impurity such as sodium and phosphorus in the glass substrate from entering the crystalline silicon thin film 4. In addition, the undercoat layer also functions as a layer for buffering the heat on the substrate 1 in a high-temperature thermal treatment process such as laser annealing. The thickness of the undercoat layer is, for example, approximately 100 nm to 2000 nm.

The gate electrode 2 is patterned on the substrate 1 in a predetermined shape. The gate electrode 2 is made of single-layer structure or a multi-layer structure of that is made of a conductive material, an alloy including the material, or the like, and is made of, for example, molybdenum (Mo), aluminum (Al), copper (Cu), tungsten (W), titanium (Ti), and chromium (Cr), and molybdenum-tungsten (MoW), for example. The thickness of the gate electrode 2 is, for example, approximately 20 nm to 500 nm.

The gate insulating film 3 is formed on the gate electrode 2. In this embodiment, the gate insulating film 3 is formed on the entire surface of the substrate 1 so as to cover the gate electrode 2. The gate insulating film 3 is made of, for example, a single-layer film of silicon oxide (SiO_{y}), silicon nitride (SiNₓ), a silicon oxynitride (SiO_{y}Nₓ) film, aluminum oxide (AlO_{z}), or tantalum oxide (TaO_{w}), or a stacked film of the materials. The thickness of the gate insulating film 3 is, for example, 50 nm to 300 nm.

In this embodiment, the crystalline silicon thin film 4 is used as the channel layer. Accordingly, silicon oxide is used as the gate insulating film 3, for example. The reason for this is that it is preferable to have good interface state between the crystalline silicon thin film 4 and the gate insulating film 3 for maintaining excellent threshold voltage characteristics of the TFT, and silicon oxide is suitable for this purpose.

The crystalline silicon thin film 4 is a first channel layer made of a semiconductor film formed on the gate insulating film 3, having a channel region in which movement of carriers are controlled by the voltage at the gate electrode 2. The channel region is a region above the gate electrode 2, and the length of the channel region in a direction of moving carrier corresponds to the gate length. The crystalline silicon thin film 4 is formed by crystallizing non-crystalline amorphous silicon, for example. An average grain size of the crystalline silicon in the crystalline silicon thin film 4 is approximately 5 nm to 1000 nm. The thickness of the crystalline silicon thin film 4 is, for example, approximately 20 nm to 100 nm.

Note that, the crystalline silicon thin film 4 may be formed not only of poly-crystal silicon having an average grain size at least 100 nm, but also of a mixed crystal structure of poly-crystal silicon and micro-crystal (μc) silicon having an average grain size at least 20 nm and smaller than 40 nm. In this case, in order to achieve excellent turn-on characteristics, at least the channel region of the crystalline silicon thin film 4 is formed of a film having a high ratio of crystalline silicon, for example.

The amorphous silicon thin film 5 is a second channel layer made of a semiconductor film formed on the crystalline silicon thin film 4 including the channel region. The amorphous silicon thin film 5 in the embodiment may be made of an intrinsic amorphous silicon film.

The amorphous silicon thin film 5 is configured such that the optical bandgap of the amorphous silicon thin film 5 and the off-state current of the thin-film transistor device 10 have a positive correlation. The optical bandgap of the amorphous silicon thin film 5 is adjusted by controlling the quality of the amorphous silicon thin film 5. Compared to the amorphous silicon thin film which is usually used for a functional layer such as a channel layer of the thin-film transistor, the amorphous silicon thin film 5 in this embodiment is less dense and has a sparse structure with regard to the film quality. The amorphous silicon thin film having such a sparse structure can be formed by setting a high gas pressure of the plasma CVD, for example, at 5 Torr.

In this embodiment, the amorphous silicon thin film 5 having the sparse structure has the optical bandgap at least 1.65 eV and at most 1.75 eV. In this case, the refractive index of the amorphous silicon thin film 5 is at least 3.9 and at most 4.2. Note that, the conventional amorphous silicon thin film regularly used has the refractive index over 4.3, which indicates a relatively dense structure with regard to the film quality. Note that, the thickness of the amorphous silicon thin film 5 in this embodiment is preferably at least 10 nm and at most 40 nm.

The insulating layer 6 is a channel protective film for protecting the channel layer (the crystalline silicon thin film 4 and the amorphous silicon thin film 5), and functions as a channel etching stopper (CES) layer for preventing the amorphous silicon thin film 5 from being etched during the etching process for forming the pair of the contact layers 7. The insulating layer 6 is formed above the crystalline silicon thin film 4 including the channel region and on the amorphous silicon semiconductor layer 5.

The insulating layer 6 is an organic material layer made of an organic material mainly containing an organic material including silicon, oxygen, and carbon, or an inorganic material layer made of silicon oxide (SiOₓ), silicon nitride (SiN_{y}), or others. Note that, the insulating layer 6 has an insulating property, and the pair of the contact layers 7 are not electrically connected.

When the insulating layer 6 is made of an organic material layer, the insulating layer 6 is formed by patterning a photosensitive application type organic material and by solidifying the organic material. In this case, the organic material for forming the insulating layer 6 is made of, for example, an organic resin material, a surface activating agent, a solvent and a photosensitizing agent. As an organic resin material which is a major component of the insulating layer 6, photosensitive or non-photosensitive organic resin material made of one or more of polyimide, acrylic, polyamide, polyimide-amide, resist, and benzocyclobutene may be used. As the surface activating agent, a surface activating agent made of a silicon compound such as siloxane may be used. As the solvent, an organic solvent such as propyleneglycol monomethylether acetate or 1,4-dioxane may be used. As the photosensitizing agent, a positive photosensitizing agent such as naphthoquinone diazide may be used. Note that, the photosensitizing agent not only includes carbon, but also sulfur. When forming the insulating layer 6 made of the organic material layer, the organic material may be formed by a coating method such as the spin coating. Other than the coating method, the insulating layer 6 may be formed by a method such as the liquid drop ejection method. An organic material may be selectively formed in a predetermined shape by using a printing method such as the screen printing or the offset printing which allow formation of the predetermined pattern.

Here, the thickness of the insulating layer 6 is 300 nm to 1000 nm, for example. The minimum thickness of the insulating layer 6 is determined for suppressing the influence of a margin due to channel etching and the fixed potential in the insulating layer, and the maximum thickness of the insulating layer 6 is determined for suppressing the reduction in the reliability of process due to an increase in the thickness of a step.

The pair of the contact layers 7 are made of an amorphous semiconductor layer having impurity at high concentration, and are formed above the crystalline silicon thin film 4 and the amorphous silicon thin film 5 with the insulating layer 6 provided in between.

The pair of the contact layers 7 is an n-type semiconductor layer in which amorphous silicon is doped with phosphorus (P) as the impurity, and is an n⁺ layer including a high concentration of impurity at least 1×10¹⁹ (atm/cm³).

The pair of the contact layers 7 is provided opposite to each other with a predetermined interval on the insulating layer 6. Each of the pair of the contact layers 7 is formed across the upper surface of the insulating layer 6 and the amorphous silicon thin film 5. In this embodiment, one of the pair of the contact layers 7 is formed across one of end portions of the insulating layer 6 and the amorphous silicon thin film 5. The contact layer 7 covers an upper part on the end portion and a side surface of the insulating layer 6, and an upper surface of the amorphous silicon thin film 5 in a side surface region of the insulating layer 6 on one side. Furthermore, the other of the pair of the contact layers 7 is formed across the other end portion of the insulating layer 6 and the amorphous silicon thin film 5. The contact layer 7 covers an upper part and a side surface of the insulating layer 6 on the other end portion, and an upper surface of the amorphous silicon thin film 5 in a side surface region of the insulating layer 6 on the other side. Note that, the thickness of the contact layer 7 may be 5 nm to 100 nm, for example.

The pair of the contact layers 7 in this embodiment are formed between the amorphous silicon thin film 5 and the source electrode 8S and the drain electrode 8D. However, the pair of the contact layers 7 is not formed on the side surfaces of the amorphous silicon thin film 5 and the side surfaces of the crystalline silicon thin film 4. Each of the pair of the contact layer 7 are formed such that the pair of the contract layers 7 are flush with the amorphous silicon thin film 5 and the crystalline silicon thin film 4.

Note that, the pair of the contract layers 7 may be formed of two layers; namely, a lower low-concentration field limiting layer (n⁻ layer) and an upper high-concentration contact layer (n⁺ layer). The low-concentration field limiting layer is doped with phosphorus at approximately 1×10¹⁷ (atm/cm³). The two layers may be continuously formed by a chemical vapor deposition (CVD) apparatus.

A pair of the source electrode 8S and the drain electrode 8D are formed opposite to each other with a predetermined interval above the crystalline silicon thin film 4 and the amorphous silicon thin film 5, on the pair of the contact layers 7, and flush with the pair of the contact layers 7.

The source electrode 8S is formed across an end portion of the insulating layer 6 (the one end portion) and the amorphous silicon thin film 5 with one of the contact layers 7 provided in between. The drain electrode 8D is provided across the other end portion of the insulating layer 6 and the amorphous silicon thin film 5 with the other one of the contract layers 7 provided in between.

In this embodiment, each of the source electrode 8S and the drain electrode 8D may be a single-layer structure or multilayer structure that is made of a conductive material, an alloy including the material, or the like, and is made of, for example, aluminum (Al), molybdenum (Mo), tungsten (W), copper (Cu), titanium (Ti), and chromium (Cr). In this embodiment, the source electrode 8S and the drain electrode 8D may be a tri-layer structure of MoW/Al/MoW, for example. Note that, the thickness of the source electrode 8S and the drain electrode 8D is, for example, approximately 100 nm to 500 nm.

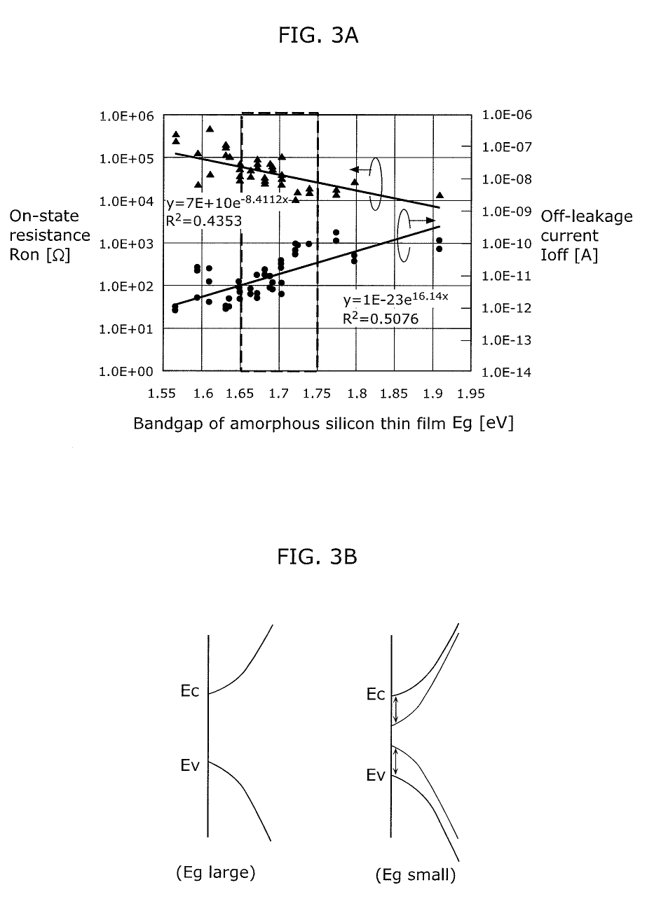

Next, actions and effects of the thin-film transistor device 10 according to the embodiment with the configuration described above shall be described with reference to FIG. 2, FIG. 3A and FIG. 3B. FIG. 2 illustrates a relationship between the optical bandgap and the off-state current of the channel layer composed of a single-layer channel layer in a general thin-film transistor device. FIG. 3A illustrates a relationship between (i) the optical bandgap and (ii) the off-leakage current (off-state current) or the on-state resistance of the amorphous silicon thin film in the thin-film transistor device according to the embodiment. FIG. 3B illustrates a relationship between (i) the optical bandgap and (ii) a conduction band or a valence band of the amorphous silicon thin film in the thin-film transistor device.

In the general thin-film transistor device made of a single-layer channel layer (amorphous silicon thin film), the off-leakage current (off-state current) Ioff generally has a relationship Ioff∝exp(−q·Eg/k/T). Stated differently, the larger the optical bandgap Eg of the channel layer is, the smaller the off-leakage current Ioff is, and the higher the temperature T is, the larger the off-leakage current Ioff is. Stated differently, in general, as illustrated in FIG. 2, it is assumed that the optical bandgap Eg and the off-leakage current Ioff of the channel layer (amorphous silicon thin film) has a negative correlation.

After diligent consideration on dependence of the optical bandgap of the amorphous silicon thin film on the off-leakage current in the thin-film transistor device having the channel layer made of the stacked structure of the crystalline silicon thin film and the amorphous silicon thin film, the inventors found out that the optical bandgap Eg and the off-leakage current Ioff of the amorphous silicon thin film (channel layer) has a positive correlation, as a phenomenon contrary to the conventional technical knowledge.

FIG. 3A illustrates dependence of the optical bandgap of the amorphous silicon thin film 5 on the on-state resistance and the off-leakage current in the thin-film transistor device 10 according to the embodiment having a two-layer structure channel layer of the crystalline silicon thin film 4 and the amorphous silicon thin film 5. FIG. 3A shows measurement results of the on-state resistance Ron and the off-leakage current Ioff in the thin-film transistor device 10 when the amorphous silicon thin films 5 were formed by controlling the film quality such that the optical bandgap of the amorphous silicon thin films 5 were in a range approximately between 1.5 and 1.9.

The results in FIG. 3A show that both (i) the optical bandgap Eg and the on-state resistance Ron and (ii) the optical bandgap Eg and the off-leakage current Ioff are proportional. Furthermore, the optical bandgap Eg and the on-state resistance Ron of the amorphous silicon thin film 5 have a negative correlation. In contrast, the optical bandgap Eg and the off-leakage current Ioff of the amorphous silicon thin film 5 does not have a negative correlation, which is a known technical knowledge, but a positive correlation. Note that, the result illustrated in FIG. 3A show cases in which the amorphous silicon thin film was 20 nm.

Here, the positive correlation between the optical bandgap Eg and the off-leakage current Ioff of the amorphous silicon thin film 5 shall be considered.

In a thin-film transistor device in which the channel layer has the stacked structure of the crystalline silicon thin film and the amorphous silicon thin film, when the optical bandgap Eg is large, the amorphous silicon thin film has a lower resistance due to the small number of defects. In this case, the voltage applied to the amorphous silicon thin film is small, making the field concentrated in the amorphous silicon thin film smaller. As a result, in the crystalline silicon thin film under the amorphous silicon thin film, the field is concentrated relative to the amorphous silicon thin film, increasing the leakage current in the crystalline silicon thin film. Accordingly, the off-leakage current Ioff in the front channel increases.

In contrast, in a thin-film transistor device in which the channel layer has the stacked structure of the crystalline silicon thin film and the amorphous silicon thin film, when the optical bandgap Eg of the amorphous silicon thin film is small, the resistance increases due to the increased number of the defects in the amorphous silicon thin film. In this case, the voltage applied to the amorphous silicon thin film increases, increasing the electric field concentrated in the amorphous silicon thin film. As a result, in the crystalline silicon thin film under the amorphous silicon thin film, the field concentration is reduced relative to the amorphous silicon thin film, reducing the leakage current in the crystalline silicon thin film. As a result, the off-leakage current Ioff in the front channel is reduced.

Note that, when the bandgap Eg of the amorphous silicon thin film is small, a tail band is extended, compared to a case in which the optical bandgap Eg is large, as illustrated in FIG. 3B. More specifically, when the optical bandgap Eg in the amorphous silicon thin film is small, a tail state with a small mobility is generated under the conduction band and on the valence band (that is, in the bandgap) due to local presence of amorphous structure.

As described above, in the thin-film transistor device having the channel layer with the stacked structure of the crystalline silicon thin film and the amorphous silicon thin film, when the optical bandgap Eg of the amorphous silicon thin film increases, the off-leakage current Ioff increases. In contrast, when the optical bandgap Eg of the amorphous silicon thin film decreases, the off-leakage current Ioff decreases. Therefore, the optical bandgap Eg and the off-leakage current Ioff of the amorphous silicon thin film have a positive correlation.

Based on the results, the inventors arrived at an idea that, in the thin-film transistor device having the channel layer with the stacked structure of the crystalline silicon thin film and the amorphous silicon thin film, the off-leakage current Ioff in the crystalline silicon thin film on the front-channel side is adjusted optimally by controlling the optical bandgap Eg of the amorphous silicon thin film on the back channel side (that is, the quality of the amorphous silicon thin film).

In the thin-film transistor device 10 according to the embodiment, the optical bandgap Eg of the amorphous silicon thin film 5 is controlled such that the off-characteristics and on-characteristics are balanced, using the positive correlation between the optical bandgap Eg of the amorphous silicon thin film 5 and the off-leakage current in the thin-film transistor device 10. More specifically, by controlling the optical bandgap of the amorphous silicon thin film 5, it is possible to suppress the off-state current while securing the on-state current without increasing the thickness of the amorphous silicon thin film 5.

As described above, the thin-film transistor device 10 according to the embodiment can suppress the off-leakage current on the front-channel side by controlling the film quality of the amorphous silicon thin film 5, while securing the on-characteristics.

In particular, in the thin-film transistor device 10 according to the embodiment, the optical bandgap of the amorphous silicon thin film 5 is at least 1.65 eV and at most 1.75 eV, such that the electric field is applied toward the amorphous silicon thin film 5, instead of the crystalline silicon thin film 4, when the thin-film transistor device 10 is turned off, that is, when a voltage for turning the thin-film transistor device off is applied to the gate electrode (a voltage that does not turn the thin-film transistor device on is applied to the gate electrode).

With this, as illustrated in FIG. 3A, the on-state resistance Ron required for the thin-film transistor device in the display device is satisfied, and the off-leakage current Ioff required as a high performance specification is satisfied.

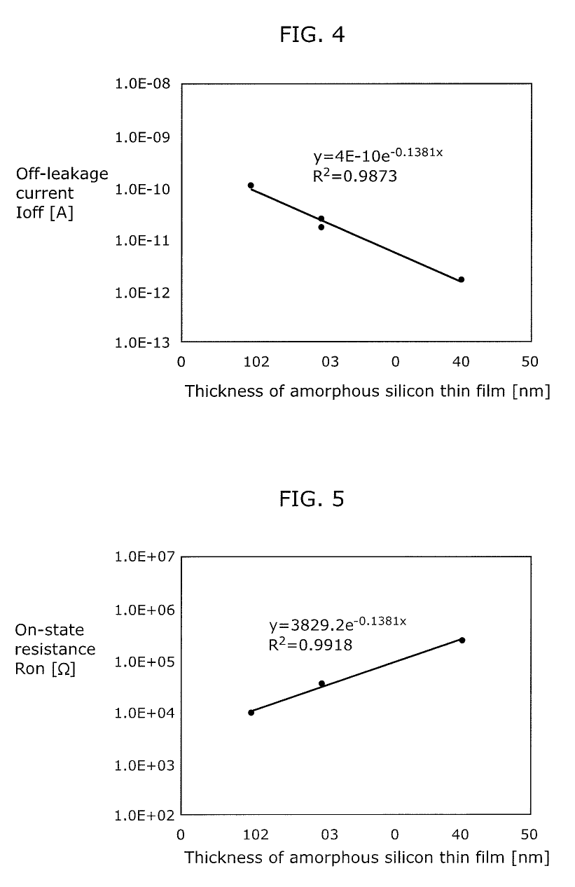

Next, the relationship between (i) the thickness of the amorphous silicon thin film 5 and (ii) the off-leakage current Ioff or the on-state resistance Ron shall be described with reference to FIG. 4 and FIG. 5. FIG. 4 illustrates the relationship between the thickness and the off-leakage current of the amorphous silicon thin film in the thin-film transistor device according to the embodiment. FIG. 5 illustrates the relationship between the thickness and the on-state resistance of the amorphous silicon thin film in the thin-film transistor device according to the embodiment. Note that, FIGS. 4 and 5 show actual measured values.

As shown in FIG. 4 and FIG. 5, at least in a range in which the thickness of the amorphous silicon thin film 5 is at least 10 nm and at most 40 nm, the thickness of the amorphous silicon thin film 5 is proportional to the off-leakage current Ioff and the on-state resistance Ron.

Furthermore, as shown in FIG. 4, the thickness of the amorphous silicon thin film 5 and the off-leakage current Ioff has a negative correlation. In contrast, the thickness of the amorphous silicon thin film 5 and the on-state resistance Ron has a positive correlation.

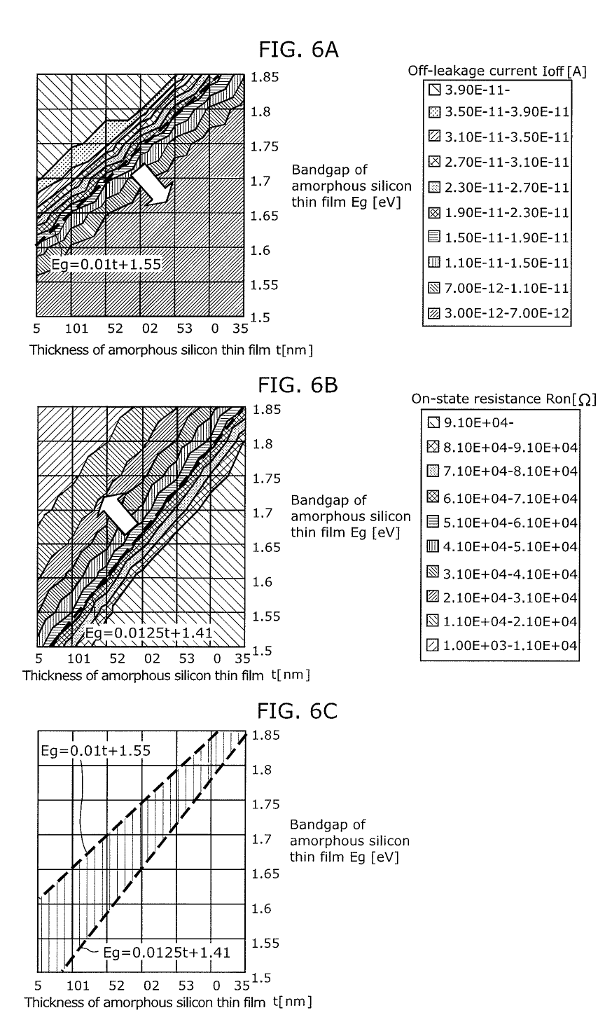

Next, the thickness t and the optical bandgap Eg of the amorphous silicon thin film 5 capable of balancing the off-leakage current Ioff and the on-state resistance Ron in the thin-film transistor device 10 according to the embodiment shall be described with reference to FIG. 6A, FIG. 6B, and FIG. 6C. FIG. 6A illustrates the relationship among the thickness of the amorphous silicon thin film, the optical bandgap and the off-leakage current of the amorphous silicon thin film in the thin-film transistor device according to the embodiment. FIG. 6B illustrates the relationship between the thickness of the amorphous silicon thin film, the optical bandgap and the on-state resistance of the amorphous silicon thin film in the thin film transistor device according to the embodiment. FIG. 6C illustrates an optimal range (process window) of the thickness and the optical bandgap of the amorphous silicon thin film in the thin-film transistor device according to the embodiment capable of balancing the off-leakage current and the on-state resistance.

As illustrated in FIG. 6A, it is preferable that the off-leakage current Ioff in the thin-film transistor device is approximately 2.0×10¹¹ A at most. Accordingly, it is preferable that the optical bandgap Eg (eV) of the amorphous silicon thin film 5 and the thickness t (nm) of the amorphous silicon thin film 5 satisfy the following expression 1.

Eg≦0.01×t+1.55 (Expression 1)

As illustrated in FIG. 6B, it is preferable that the on-state resistance Ron in the thin-film transistor device is approximately 5.0×10⁴Ω at most. Accordingly, it is preferable that the optical bandgap Eg (eV) of the amorphous silicon thin film 5 and the thickness t (nm) of the amorphous silicon thin film 5 in this embodiment satisfy the following expression 2.

Eg≧0.0125×t+1.41 (Expression 2)

Therefore, the optimal range of the thickness t and the optical bandgap Eg in the amorphous silicon thin film 5 capable of balancing the off-leakage current Ioff and the on-state resistance Ron is a range satisfying the relational expressions (Expression 1) and (Expression 2) at the same time, as illustrated in FIG. 6C.

As described above, with regard to the amorphous silicon thin film 5, it is possible to balance the off-leakage current Ioff and the on-state resistance Ron by having the thickness t and the optical bandgap Eg satisfying (Expression 1) and (Expression 2) at the same time.

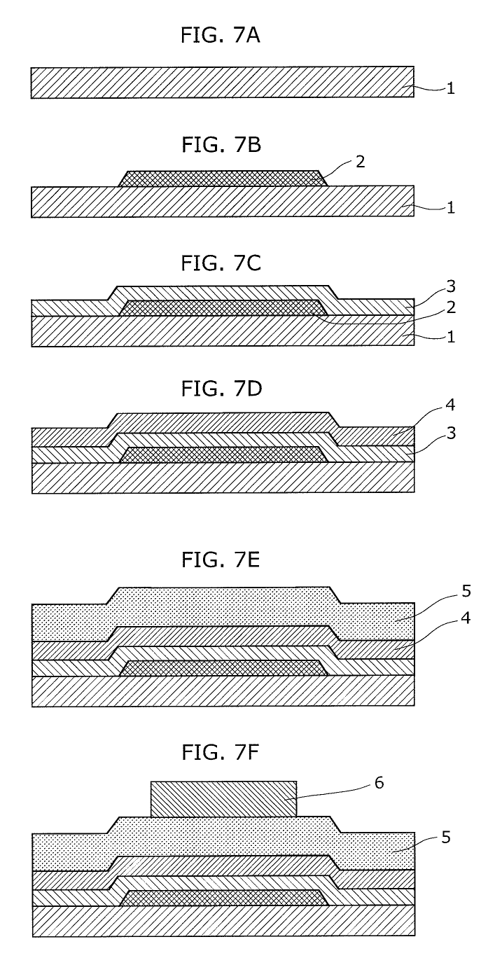

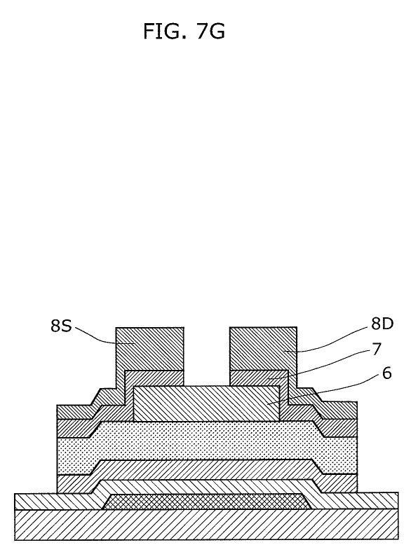

Next, the following shall describe a method for manufacturing the thin-film transistor device 10 according to this embodiment with reference to FIGS. 7A to 7G. FIG. 7A to FIG. 7G are cross-sectional views schematically illustrating the process in the method for manufacturing the thin-film transistor device according to this embodiment.

First, as illustrated in FIG. 7A, the substrate 1 is prepared. As the substrate 1, a glass substrate may be used, for example. Note that, an undercoat layer made of a silicon nitride film, a silicon oxide film, or a silicon oxynitride film may be formed on the substrate 1 by the plasma CVD or others, before the gate electrode 2 is formed.

Next, as illustrated in FIG. 7B, the gate electrode 2 in a predetermined shape is formed above the substrate 1 by patterning. For example, the gate electrodes 2 in the predetermined shape is formed by forming a gate metal film made of molybdenum-tungsten (MoW) or others on the entire surface of the substrate 1 through sputtering, and by patterning the gate metal film using the photolithography and the wet etching. The wet etching on MoW may be performed using a chemical solution which is a mixture of trihydrogen phosphate (H₃PO₄), nitric acid (HNO₃), acetic acid (CH₃COOH) and water in a predetermined ratio, for example.

Next, as illustrated in FIG. 7C, the gate insulating film 3 is formed above the substrate 1. For example, the gate insulating film 3 made of silicon oxide is formed on the entire surface above the substrate 1 by the plasma CVD or others so as to cover the gate electrode 2. Silicon oxide is formed, for example, by introducing silane gas (SiH₄) and nitrous oxide gas (N₂O) in a predetermined ratio of concentration, for example.

Next, as illustrated in FIG. 7D, the crystalline silicon thin film 4 made of poly-crystal silicon is formed on the gate insulating film 3. In this case, first, a non-crystalline silicon thin film made of amorphous silicon is formed by the plasma CVD or others on the gate insulating film 3, and a dehydrogenation annealing is performed. After that, the non-crystalline silicon thin film is annealed for crystallization so as to form the crystalline silicon thin film 4. The non-crystalline silicon film is formed by introducing silane gas (SiH₄) and hydrogen gas (H₂) in a predetermined ratio of concentration, for example.

Note that, in this embodiment, the amorphous silicon thin film is crystallized by the laser annealing using the excimer laser. As the method for crystallization, the laser annealing using a pulse laser with a wavelength approximately 370 nm to 900 nm, the laser annealing using the continuous wave laser with a wavelength approximately 370 nm to 900 nm, or the annealing by the rapid thermal processing (RTP) may be used. Furthermore, the crystalline silicon thin film may be formed by a method such as direct growth by the CVD, instead of crystallizing the non-crystalline silicon thin film.

Subsequently, by performing hydrogen plasma treatment on the crystalline silicon thin film 4, silicon atoms in the crystalline silicon thin film 4 are hydrotreated. The hydrogen plasma treatment is performed by generating hydrogen plasma from gas containing hydrogen gas such as H₂, H₂/argon (Ar), using a radio frequency (RF) power, and by irradiating the polycrystalline semiconductor layer 4 with the hydrogen plasma. With the hydrogen plasma treatment, the dangling bond (defect) of silicon atoms are hydrogen terminated. As a result, the crystal defect density of the crystalline silicon thin film 4 is reduced, improving the crystallinity.

Next, as illustrated in FIG. 7E, the amorphous silicon thin film 5 (amorphous silicon film) is formed on the crystalline silicon thin film 4. In this embodiment, the amorphous silicon thin film 5 is formed by a parallel-plate electrode type RF plasma CVD apparatus having parallel-plate electrodes. In this case, as the film-forming condition for forming the amorphous silicon thin film 5, the temperature (growth temperature) of the substrate 1 set in the apparatus is at least 300° C. and at most 400° C., silane gas (SiH₄) is introduced to the apparatus as the source gas at a flow rate at least 50 sccm and at most 65 sccm, while introducing hydrogen gas (H₂) at least 6 sccm and at most 17 sccm. The pressure in the apparatus is at least 450 Pa and at most 850 Pa, and the distance between the parallel-plate electrodes is at least 350 mm and at most 680 mm. Furthermore, the RF power density to be applied to the parallel-plate electrodes is at least 0.0685W/cm² and at most 0.274 W/cm². As an inert gas introduced with the source gas, other than the hydrogen gas (H₂), argon gas (Ar) or helium gas (He) may be used.

In this embodiment, the amorphous silicon thin film 5 was formed under the condition in which the growth temperature was 350 ° C., the pressure was 5 Torr, the RF power density was 0.0822 W/cm², the flow rate of silane gas was 60 sccm, the flow rate of the hydrogen gas was 10 sccm, and the distance between the electrodes was 375 nm to 600 nm.

By forming the amorphous silicon thin film 5 under the film-forming condition described above, the amorphous silicon thin film 5 having the optical bandgap of 1.65 eV to 1.75 eV is formed. Stated differently, the amorphous silicon thin film 5 capable of securing the on-state current and suppressing the off-state current can be formed.

Next, as illustrated in FIG. 7F, the insulating layer 6 is formed on the amorphous silicon semiconductor layer 5. For example, the insulating layer 6 made of an organic film is formed by applying a predetermined organic material on the amorphous silicon semiconductor layer 5 by the predetermined coating method and baking the organic material.

In this embodiment, polysiloxane is applied on the amorphous silicon semiconductor layer 5 first, and the spin coating is performed. With this, the insulating layer 6 is formed on the entire surface of the amorphous silicon semiconductor thin film 5. Subsequently, the insulating layer 6 is pre-baked. After that, the insulating layer 6 in the predetermined shape is formed by exposure and development using a photo mask. After that, post-baking on the insulating layer 6 is performed. With this, the insulating layer 6 which functions as the channel protective layer is formed.

Next, as illustrated in FIG. 7G, the pair of contact layers 7 is formed on the amorphous silicon thin film 5, interposing the organic protective film 6. Subsequently, the source electrode 8S and the drain electrode 8D are formed on the pair of the contact layers 7.

In this case, first, an amorphous silicon film doped with an impurity of pentavalent element such as phosphorous (P) is formed on the amorphous silicon thin film 5 by the plasma CVD as a film for forming the contact layer 7 covering the insulating layer 6. After that, a source-drain metal film for forming the source electrode 8S and the drain electrode 8D is formed on the film for the contract layer 7 by sputtering. Subsequently, a resist having a predetermined shape is patterned on the source-drain metal film for forming the source electrode 8S and the drain electrode 8D in the predetermined shape, and the source-drain metal film is patterned by performing wet etching using the resist as a mask. With this, as illustrated in FIG. 7G, the source electrode 8S and the drain electrode 8D in the predetermined shape are formed. Here, note that the film for the contact layer functions as an etching stopper.

Subsequently, the resist on the source electrode 8S and the drain electrode 8D is removed, and etching such as dry etching is performed using the source electrode and the drain electrode 8D as masks so as to pattern the film for the contract layer. At the same time, the amorphous silicon semiconductor layer 5 and the crystalline silicon thin film 4 are patterned into an island shape. Accordingly, as illustrated in FIG. 7G, the pair of contact layers 7 in the predetermined shape are formed, and the amorphous silicon thin film 5 and the crystalline silicon thin film 4 patterned into the island shape are formed.

With the formation process described above, side surfaces of the pair of the source electrode 8S and the drain electrode 8D, the pair of the contact layers 7, the amorphous silicon thin film 5, and the crystalline silicon thin film 4 are flush with one another. To put it differently, the pair of the contact layers 7 are not formed on the side surfaces of the source electrodes 8S, the side surfaces of the drain electrode 8D, the side surfaces of the amorphous silicon thin film 5, and the side surfaces of the crystalline silicon thin film 4.

With the process described above, the thin-film transistor device 10 according to the embodiment is manufactured. Note that, a passivation film made of an inorganic material such as SiN may be formed to cover the entire thin-film transistor device 10 illustrated in FIG. 7G.

The thin-film transistor device 10 according to this embodiment with the configuration described above may be used as a display device such as an organic EL display device, a liquid crystal display device, and others. In addition, the display device may be used as a flat-panel display, and may be applicable to electronic devices such as television sets, personal computers, or mobile phones.

Although only an exemplary embodiment of the thin-film transistor device and the method for manufacturing the thin-film transistor device according to the present disclosure has been described in detail above, the present disclosure is not limited to the embodiment.

For example, the channel-protective thin-film semiconductor device using the insulating layer 6 (channel protective film) is described in the embodiment. However, the present disclosure is applicable to a channel-etching thin-film semiconductor device in which no insulating layer 6 (channel protective film) is used.

The insulating layer 6 is made of an organic material in the embodiment. However, the insulating layer 6 may be formed by using an inorganic material such as silicon oxide.

Those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The thin-film transistor device according to the present disclosure is widely applicable to display devices such as television sets, personal computers, and mobile phones, or various electronic devices having thin-film transistors.

1. A thin-film transistor device which is a bottom-gate thin-film transistor device, comprising:
a gate electrode above a substrate;
a gate insulating film above the gate electrode;
a crystalline silicon thin film comprising a channel region, the crystalline silicon thin film being above the gate insulating film and having a channel region;
an amorphous silicon thin film above the crystalline silicon thin film including the channel region; and
a source electrode and a drain electrode above the amorphous silicon thin film,
wherein an optical bandgap of the amorphous silicon thin film and an off-state current of the thin-film transistor device have a positive correlation.

2. The thin-film transistor device according to claim 1,
wherein an optical bandgap of the amorphous silicon thin film is at least 1.65 eV and at most 1.75 eV, and
a potential of the amorphous silicon thin film is higher than a potential of the crystalline silicon thin film when an off-state voltage of the thin-film transistor device is applied to the gate electrode.

3. The thin-film transistor device according to claim 1, wherein expressions Eg≦0.01×t+1.55 and Eg≧0.0125×t+1.41 are satisfied, where Eg (eV) represents an optical bandgap of the amorphous silicon thin film and t (nm) represents a thickness of the amorphous silicon thin film.

4. The thin-film transistor device according to claim 1, wherein the amorphous silicon thin film has a thickness of at least 10 nm and at most 40 nm.

5. The thin-film transistor device according to claim 1, further comprising:
an insulating layer above the gate electrode and above the amorphous silicon thin film.

6. The thin-film transistor device according to claim 1, further comprising:
a pair of contact layers formed between the amorphous silicon thin film and the source electrode and between the amorphous silicon thin film and the drain electrode,
wherein the pair of contact layers is not on a side surface of the amorphous silicon thin film or on a side surface of the crystalline silicon thin film.

7. A method for manufacturing a thin-film transistor device which is a bottom-gate thin-film transistor device, the method comprising:
preparing a substrate;
forming a gate electrode above the substrate;
forming a gate insulating film above the gate electrode;
forming, above the gate insulating film, a crystalline silicon thin film having a channel region;
forming an amorphous silicon thin film above the crystalline silicon thin film including the channel region; and
forming a source electrode and a drain electrode above the amorphous silicon thin film,
wherein the amorphous silicon thin film is formed such that an optical bandgap of the amorphous silicon thin film and an off-state current of the thin-film transistor device have a positive correlation.

8. The method for manufacturing the thin-film transistor device according to claim 7,
wherein the amorphous silicon thin film is formed by a radio-frequency (RF) plasma chemical vapor deposition apparatus having parallel-plate electrodes under a film-forming condition in which:
a temperature of the substrate set in the apparatus is at least 300° C. and at most 400° C.;
SiH₄ gas is introduced to the apparatus at a flow rate at least 50 sccm and at most 60 sccm, and H₂ gas is introduced to the apparatus at a flow rate at least 6 sccm and at most 17 sccm;
a pressure in the apparatus is at least 450 Pa and at most 850 Pa;
a distance between the parallel-plate electrodes is at least 350 mm and at most 680 mm; and
a density of an RF power applied to the parallel-plate electrodes is at least 0.0685 W/cm² and at most 0.274 W/cm².

9. The method for manufacturing the thin-film transistor device according to claim 8,
wherein the amorphous silicon thin film is formed such that an optical bandgap of the amorphous silicon thin film is at least 1.65 eV and at most 1.75 eV, and when a voltage is not applied to the gate electrode, a potential of the amorphous silicon thin film is higher than a potential of the crystalline silicon thin film.

10. The method for manufacturing the thin-film transistor device according to claim 8,
wherein the amorphous silicon thin film is formed such that expressions Eg≦0.01×t+1.55 and Eg≧0.0125×t+1.41 are satisfied, where Eg (eV) represents an optical bandgap of the amorphous silicon thin film and t (nm) represents a thickness of the amorphous silicon thin film.

11. The method for manufacturing the thin-film transistor device according to claim 7, further comprising:
forming an insulating layer above the gate electrode and above the amorphous silicon thin film, after the amorphous silicon thin film is formed and before the source electrode and the drain electrode are formed.

12. A thin-film transistor device which is a bottom-gate thin-film transistor device, comprising:
a gate electrode above a substrate;
a gate insulating film above the gate electrode;
a crystalline silicon thin film comprising a channel region, the crystalline silicon thin film being above the gate insulating film;
an amorphous silicon thin film above the crystalline silicon thin film including the channel region; and
a source electrode and a drain electrode above the amorphous silicon thin film,
wherein an optical bandgap of the amorphous silicon thin film is at least 1.65 eV and at most 1.75 eV, and
a potential of the amorphous silicon thin film is higher than a potential of the crystalline silicon thin film when an off-state voltage of the thin-film transistor device is applied to the gate electrode, and
wherein expressions Eg≦0.01×t+1.55
and Eg≧0.0125×t+1.41 are satisfied, where Eg (eV) represents the optical bandgap of the amorphous silicon thin film and t (nm) represents a thickness of the amorphous silicon thin film.
